(19) United States
(12) Patent Application Publication
(10) Pub. No.: US 2024/0053905 A1
(43) Pub. Date: Feb. 15, 2024

(54) COMPRESSION AND DECOMPRESSION OF TRIM DATA

(71) Applicant: Micron Technology, Inc., Boise, ID (US)

(72) Inventors: Reshmi Basu, Boise, ID (US); Jonathan S. Parry, Boise, ID (US); Giuseppe Cariello, Boise, ID (US); Stephen Hanna, Fort Collins, CO (US)

(21) Appl. No.: 17/888,309

(22) Filed: Aug. 15, 2022

(51) Int. Cl. G06F 3/06

(52) U.S. Cl. CPC G06F 3/0631; G06F 3/0659; G06F 3/0683; G06F 3/0604

(57) ABSTRACT

Methods, systems, and devices for compression and decompression of trim data are described. A memory system may store one or more trim settings to a volatile memory in a compressed manner, and may expand (e.g., decompress) the data as part of a write operation to a non-volatile memory (e.g., during a start-up procedure). For example, compressed (e.g., non-expanded) data including trim settings may be stored to a volatile memory, and a portion of the array of volatile memory cells may be temporarily allocated to expand the data (e.g., copy the data, invert the data, copy the inverted data). Once the data is expanded, it may be stored in the non-volatile memory, and the temporarily allocated portion of the array of volatile memory cells may be reallocated (e.g., allocated for another purpose). The expanded data may include multiple copies and inverted copies of the trim settings.

### FIELD OF TECHNOLOGY

The following relates to one or more systems for memory, including compression and decompression of trim data.

### BACKGROUND

Memory devices are widely used to store information in various electronic devices such as computers, user devices, wireless communication devices, cameras, digital displays, and the like. Information is stored by programming memory cells within a memory device to various states. For example, binary memory cells may be programmed to one of two supported states, often corresponding to a logic 1 or a logic 0. In some examples, a single memory cell may support more than two possible states, any one of which may be stored by the memory cell. To access information stored by a memory device, a component may read (e.g., sense, detect, retrieve, identify, determine, evaluate) the state of one or more memory cells within the memory device. To store information, a component may write (e.g., program, set, assign) one or more memory cells within the memory device to corresponding states.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), 3-dimensional cross-point memory (3D cross point), not-or (NOR) and not-and (NAND) memory devices, and others. Memory devices may be described in terms of volatile configurations or non-volatile configurations. Volatile memory cells (e.g., DRAM) may lose their programmed states over time unless they are periodically refreshed by an external power source. Non-volatile memory cells (e.g., NAND) may maintain their programmed states for extended periods of time even in the absence of an external power source.

### BRIEF DESCRIPTION OF THE DRAWINGS

FIG. 1 illustrates an example of a system that supports compression and decompression of trim data in accordance with examples as disclosed herein.

FIG. 2 illustrates an example of a system that supports compression and decompression of trim data in accordance with examples as disclosed herein.

FIG. 3 illustrates an example of a system that supports compression and decompression of trim data in accordance with examples as disclosed herein.

FIG. 4 illustrates an example of a process flow diagram that supports compression and decompression of trim data in accordance with examples as disclosed herein.

FIG. 5 shows a block diagram of a memory system that supports compression and decompression of trim data in accordance with examples as disclosed herein.

FIG. 6 shows a flowchart illustrating a method or methods that support compression and decompression of trim data in accordance with examples as disclosed herein.

### DETAILED DESCRIPTION

In some examples, a memory system may operate in accordance with trim settings stored in non-volatile memory (e.g., in one or more blocks of non-volatile memory cells), where the trim settings may include a plurality parameters that define operations and functions of the memory device. Because errors in the trim settings may cause the memory system to fail, the memory system may be configured to store one or more copies of at least some of, if not all of, the trim settings to serve as a backup (e.g., one or more backups) in case the primary trim settings include an error. In such examples, the memory system may load data (e.g., a data packet) including multiple copies of the trim settings to the non-volatile memory (e.g., from a volatile memory cache, one or more blocks of volatile memory cells) as part of a start-up procedure. However, because the data includes multiple copies of the trim settings, the data may occupy a relatively large amount of space of the volatile memory, thereby reducing storage capabilities and overall performance of the memory system, among other issues.

In accordance with examples as disclosed herein, a memory system may store one or more trim settings to a volatile memory in a compressed manner, and may expand (e.g., decompress) the data as part of a write operation to a non-volatile memory (e.g., during a start-up procedure). For example, compressed (e.g., non-expanded) trim data may be stored to a volatile memory, and a portion of the volatile memory (e.g., one or more blocks of volatile memory cells) may be allocated (e.g., temporarily allocated) for expanding the data (e.g., to copy the data, to invert the data, to copy the inverted data). Once the data is expanded, it may be stored in the non-volatile memory and the temporarily allocated portion of the volatile memory may be reallocated (e.g., allocated for another purpose). The expanded data may include multiple copies of the trim settings, and such redundancies may serve as backup copies of the trim data to reduce or mitigate the likelihood of failures (e.g., failures of the memory system). Moreover, by storing compressed data in the volatile memory, the storage capabilities and overall performance of the memory system may be improved, among other advantages.

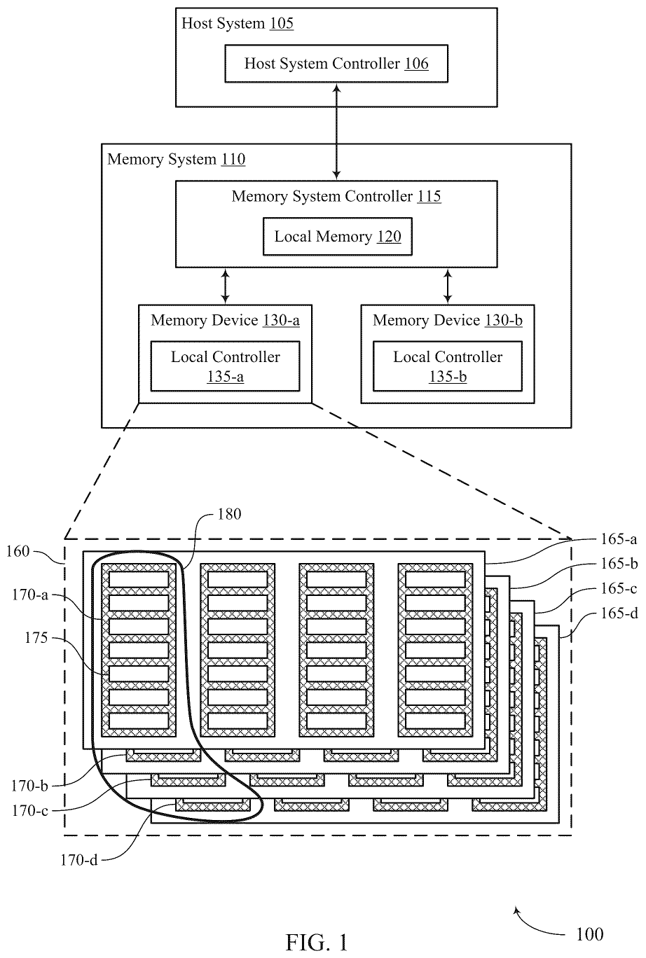

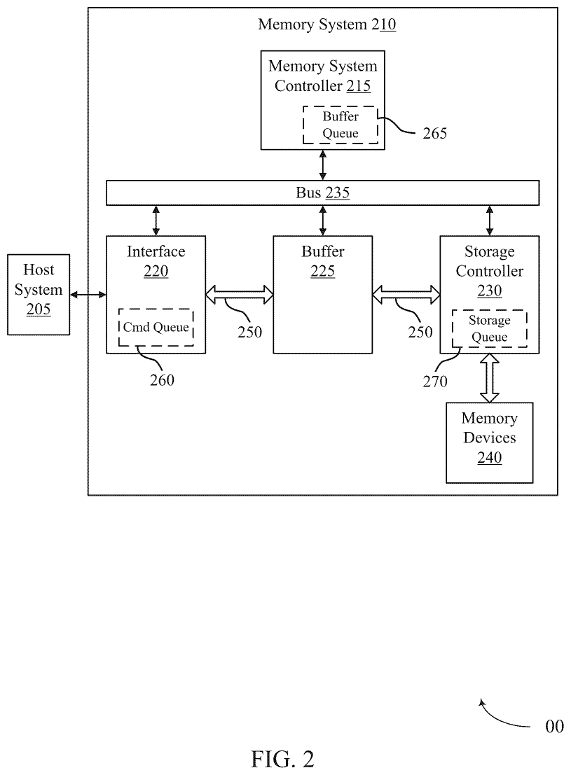

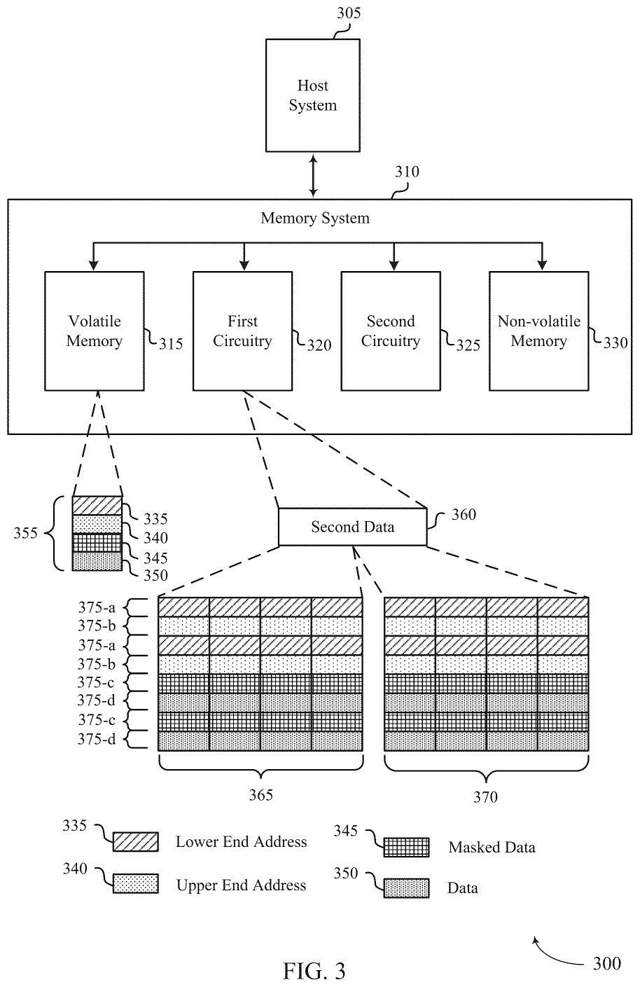

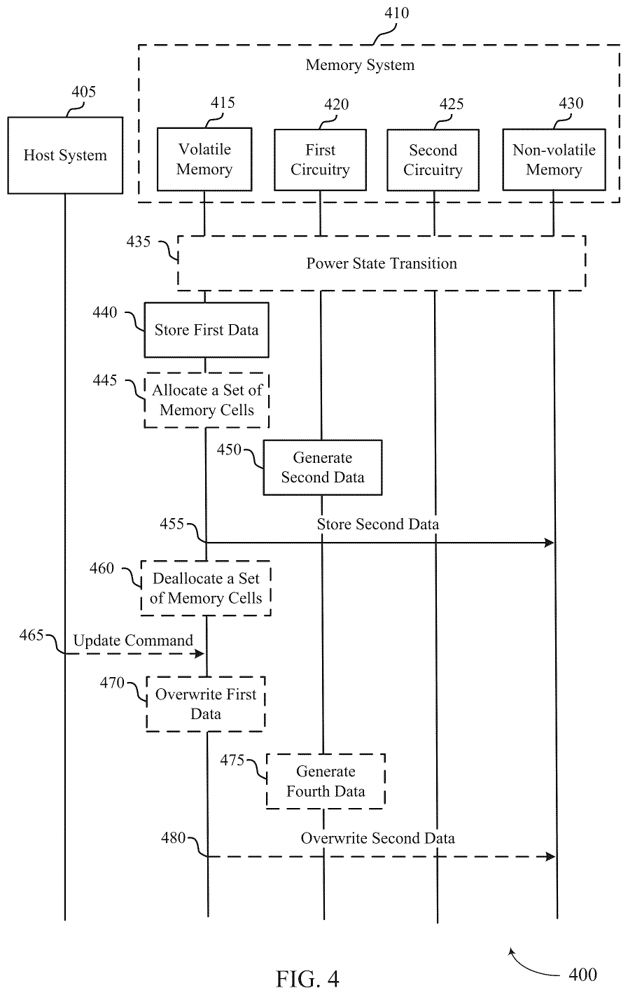

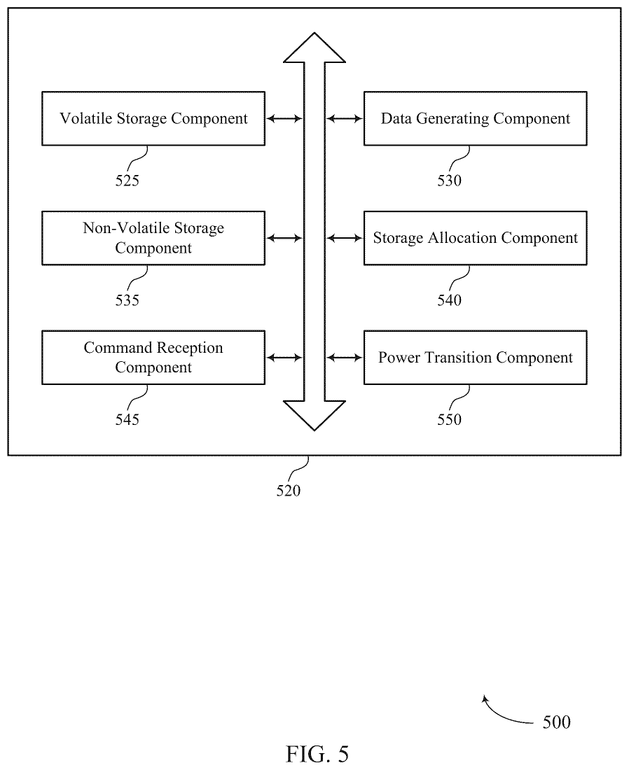

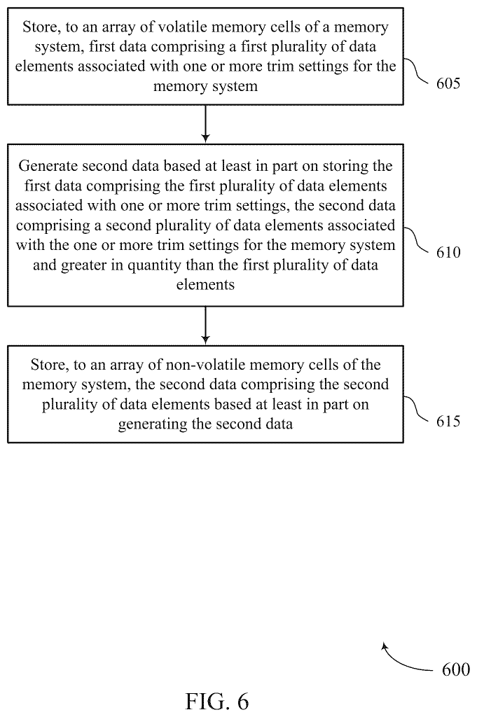

Features of the disclosure are initially described in the context of systems, devices, and circuits with reference to FIGS. 1 and 2. Features of the disclosure are described in the context of a system and a process flow diagram with reference to FIGS. 3 and 4. These and other features of the disclosure are further illustrated by and described in the context of an apparatus diagram and flowchart that relate to compression and decompression of trim data with reference to FIGS. 5 and 6.

FIG. 1 illustrates an example of a system 100 that supports compression and decompression of trim data in accordance with examples as disclosed herein. The system 100 includes a host system 105 coupled with a memory system 110.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other possibilities.

The system 100 may be included in a computing device such as a desktop computer, a laptop computer, a network server, a mobile device, a vehicle (e.g., airplane, drone, train, automobile, or other conveyance), an Internet of Things (IoT) enabled device, an embedded computer (e.g., one included in a vehicle, industrial equipment, or a networked commercial device), or any other computing device that includes memory and a processing device.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations—which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally or alternatively include static random access memory (SRAM) or other memory that may be used by the memory system controller 115 for internal storage or calculations, for example, related to the functions ascribed herein to the memory system controller 115. Additionally or alternatively, the local memory 120 may serve as a cache for the memory system controller 115. For example, data may be stored in the local memory 120 if read from or written to a memory device 130, and the data may be available within the local memory 120 for subsequent retrieval for or manipulation (e.g., updating) by the host system 105 (e.g., with reduced latency relative to a memory device 130) in accordance with a cache policy.

Although the example of the memory system 110 in FIG. 1 has been illustrated as including the memory system controller 115, in some cases, a memory system 110 may not include a memory system controller 115. For example, the memory system 110 may additionally or alternatively rely upon an external controller (e.g., implemented by the host system 105) or one or more local controllers 135, which may be internal to memory devices 130, respectively, to perform the functions ascribed herein to the memory system controller 115. In general, one or more functions ascribed herein to the memory system controller 115 may, in some cases, be performed instead by the host system 105, a local controller 135, or any combination thereof. In some cases, a memory device 130 that is managed at least in part by a memory system controller 115 may be referred to as a managed memory device. An example of a managed memory device is a managed NAND (MNAND) device.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (RAM) (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on a same die or within a same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b.

In some cases, a memory device 130 may be or include a NAND device (e.g., NAND flash device). A memory device 130 may be or include a memory die 160. For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170, and in some cases, concurrent operations may take place within different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in a same page 175 may share (e.g., be coupled with) a common word line, and memory cells in a same string may share (e.g., be coupled with) a common digit line (which may alternatively be referred to as a bit line).

For some NAND architectures, memory cells may be read and programmed (e.g., written) at a first level of granularity (e.g., at the page level of granularity) but may be erased at a second level of granularity (e.g., at the block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

The system 100 may include any quantity of non-transitory computer readable media that support compression and decompression of trim data. For example, the host system 105 (e.g., a host system controller 106), the memory system 110 (e.g., a memory system controller 115), or a memory device 130 (e.g., a local controller 135) may include or otherwise may access one or more non-transitory computer readable media storing instructions (e.g., firmware, logic, code) for performing the functions ascribed herein to the host system 105, the memory system 110, or a memory device 130. For example, such instructions, if executed by the host system 105 (e.g., by a host system controller 106), by the memory system 110 (e.g., by a memory system controller 115), or by a memory device 130 (e.g., by a local controller 135), may cause the host system 105, the memory system 110, or the memory device 130 to perform associated functions as described herein.

In some examples, a memory system 110 may operate in accordance with one or more trim settings stored to the memory device 130-a (e.g., in one or more physical blocks 170 of the memory device 130-a). Because errors in the trim settings may cause the memory system 110 to fail, the memory system 110 may be configured to store one or more copies of the trim settings to serve as a backup in case the primary trim settings include an error. In such examples, the memory system 110 may load data (e.g., a data packet) including multiple copies of the trim settings to the non-volatile memory (e.g., from a volatile memory cache, one or more physical blocks 170) as part of a start-up procedure, where the data is written to the volatile memory from a register (e.g., non-volatile register) of the memory system 110.

In accordance with examples as disclosed herein, a memory system 110 may store one or more trim settings to a volatile memory in a compressed manner, and may expand (e.g., decompress) the data as part of a write operation to a memory device 130-a (e.g., a non-volatile memory device 130-a). For example, compressed (e.g., non-expanded) trim data may be stored to a volatile memory (e.g., a local memory 120), and a portion of the volatile memory may be temporarily allocated to expand the data (e.g., to copy the data, to invert the data, to copy the inverted data). Once the data is expanded, it may be stored in the memory device 130-a, and the temporarily allocated portion of the local memory 120 may be reallocated (e.g., allocated for another purpose). The expanded data may include multiple copies of the trim settings, and such redundancies may ensure proper operation of the memory system 110 (e.g., in accordance with the trim settings). Moreover, by storing compressed data in the local memory 120, storage capabilities and overall performance of the memory system 110 may be improved.

FIG. 2 illustrates an example of a system 200 that supports compression and decompression of trim data in accordance with examples as disclosed herein. The system 200 may be an example of a system 100 as described with reference to FIG. 1 or aspects thereof. The system 200 may include a memory system 210 configured to store data received from the host system 205 and to send data to the host system 205, if requested by the host system 205 using access commands (e.g., read commands or write commands). The system 200 may implement aspects of the system 100 as described with reference to FIG. 1. For example, the memory system 210 and the host system 205 may be examples of the memory system 110 and the host system 105, respectively.

The memory system 210 may include memory devices 240 to store data transferred between the memory system 210 and the host system 205, e.g., in response to receiving access commands from the host system 205, as described herein. The memory devices 240 may include one or more memory devices as described with reference to FIG. 1. For example, the memory devices 240 may include NAND memory, PCM, self-selecting memory, 3D cross point or other chalcogenide-based memories, FERAM, MRAM, NOR (e.g., NOR flash) memory, STT-MRAM, CBRAM, RRAM, or OxRAM.

The memory system 210 may include a storage controller 230 for controlling the passing of data directly to and from the memory devices 240, e.g., for storing data, retrieving data, and determining memory locations in which to store data and from which to retrieve data. The storage controller 230 may communicate with memory devices 240 directly or via a bus (not shown) using a protocol specific to each type of memory device 240. In some cases, a single storage controller 230 may be used to control multiple memory devices 240 of the same or different types. In some cases, the memory system 210 may include multiple storage controllers 230, e.g., a different storage controller 230 for each type of memory device 240. In some cases, a storage controller 230 may implement aspects of a local controller 135 as described with reference to FIG. 1.

The memory system 210 may additionally include an interface 220 for communication with the host system 205 and a buffer 225 for temporary storage of data being transferred between the host system 205 and the memory devices 240. The interface 220, buffer 225, and storage controller 230 may be for translating data between the host system 205 and the memory devices 240, e.g., as shown by a data path 250, and may be collectively referred to as data path components.

Using the buffer 225 to temporarily store data during transfers may allow data to be buffered as commands are being processed, thereby reducing latency between commands and allowing arbitrary data sizes associated with commands. This may also allow bursts of commands to be handled, and the buffered data may be stored or transmitted (or both) once a burst has stopped. The buffer 225 may include relatively fast memory (e.g., some types of volatile memory, such as SRAM or DRAM) or hardware accelerators or both to allow fast storage and retrieval of data to and from the buffer 225. The buffer 225 may include data path switching components for bi-directional data transfer between the buffer 225 and other components.

The temporary storage of data within a buffer 225 may refer to the storage of data in the buffer 225 during the execution of access commands. That is, upon completion of an access command, the associated data may no longer be maintained in the buffer 225 (e.g., may be overwritten with data for additional access commands). In addition, the buffer 225 may be a non-cache buffer. That is, data may not be read directly from the buffer 225 by the host system 205. For example, read commands may be added to a queue without an operation to match the address to addresses already in the buffer 225 (e.g., without a cache address match or lookup operation).

The memory system 210 may additionally include a memory system controller 215 for executing the commands received from the host system 205 and controlling the data path components in the moving of the data. The memory system controller 215 may be an example of the memory system controller 115 as described with reference to FIG. 1. A bus 235 may be used to communicate between the system components.

In some cases, one or more queues (e.g., a command queue 260, a buffer queue 265, and a storage queue 270) may be used to control the processing of the access commands and the movement of the corresponding data. This may be beneficial, e.g., if more than one access command from the host system 205 is processed concurrently by the memory system 210. The command queue 260, buffer queue 265, and storage queue 270 are depicted at the interface 220, memory system controller 215, and storage controller 230, respectively, as examples of a possible implementation. However, queues, if used, may be positioned anywhere within the memory system 210.

Data transferred between the host system 205 and the memory devices 240 may take a different path in the memory system 210 than non-data information (e.g., commands, status information). For example, the system components in the memory system 210 may communicate with each other using a bus 235, while the data may use the data path 250 through the data path components instead of the bus 235. The memory system controller 215 may control how and if data is transferred between the host system 205 and the memory devices 240 by communicating with the data path components over the bus 235 (e.g., using a protocol specific to the memory system 210).

If a host system 205 transmits access commands to the memory system 210, the commands may be received by the interface 220, e.g., according to a protocol (e.g., a UFS protocol or an eMMC protocol). Thus, the interface 220 may be considered a front end of the memory system 210. Upon receipt of each access command, the interface 220 may communicate the command to the memory system controller 215, e.g., via the bus 235. In some cases, each command may be added to a command queue 260 by the interface 220 to communicate the command to the memory system controller 215.

The memory system controller 215 may determine that an access command has been received based on the communication from the interface 220. In some cases, the memory system controller 215 may determine the access command has been received by retrieving the command from the command queue 260. The command may be removed from the command queue 260 after it has been retrieved therefrom, e.g., by the memory system controller 215. In some cases, the memory system controller 215 may cause the interface 220, e.g., via the bus 235, to remove the command from the command queue 260.

Upon the determination that an access command has been received, the memory system controller 215 may execute the access command. For a read command, this may mean obtaining data from the memory devices 240 and transmitting the data to the host system 205. For a write command, this may mean receiving data from the host system 205 and moving the data to the memory devices 240.

In either case, the memory system controller 215 may use the buffer 225 for, among other things, temporary storage of the data being received from or sent to the host system 205. The buffer 225 may be considered a middle end of the memory system 210. In some cases, buffer address management (e.g., pointers to address locations in the buffer 225) may be performed by hardware (e.g., dedicated circuits) in the interface 220, buffer 225, or storage controller 230.

To process a write command received from the host system 205, the memory system controller 215 may first determine if the buffer 225 has sufficient available space to store the data associated with the command. For example, the memory system controller 215 may determine, e.g., via firmware (e.g., controller firmware), an amount of space within the buffer 225 that may be available to store data associated with the write command.

In some cases, a buffer queue 265 may be used to control a flow of commands associated with data stored in the buffer 225, including write commands. The buffer queue 265 may include the access commands associated with data currently stored in the buffer 225. In some cases, the commands in the command queue 260 may be moved to the buffer queue 265 by the memory system controller 215 and may remain in the buffer queue 265 while the associated data is stored in the buffer 225. In some cases, each command in the buffer queue 265 may be associated with an address at the buffer 225. That is, pointers may be maintained that indicate where in the buffer 225 the data associated with each command is stored. Using the buffer queue 265, multiple access commands may be received sequentially from the host system 205 and at least portions of the access commands may be processed concurrently.

If the buffer 225 has sufficient space to store the write data, the memory system controller 215 may cause the interface 220 to transmit an indication of availability to the host system 205 (e.g., a “ready to transfer” indication), e.g., according to a protocol (e.g., a UFS protocol or an eMMC protocol). As the interface 220 subsequently receives from the host system 205 the data associated with the write command, the interface 220 may transfer the data to the buffer 225 for temporary storage using the data path 250. In some cases, the interface 220 may obtain from the buffer 225 or buffer queue 265 the location within the buffer 225 to store the data. The interface 220 may indicate to the memory system controller 215, e.g., via the bus 235, if the data transfer to the buffer 225 has been completed.

Once the write data has been stored in the buffer 225 by the interface 220, the data may be transferred out of the buffer 225 and stored in a memory device 240. This may be done using the storage controller 230. For example, the memory system controller 215 may cause the storage controller 230 to retrieve the data out of the buffer 225 using the data path 250 and transfer the data to a memory device 240. The storage controller 230 may be considered a back end of the memory system 210. The storage controller 230 may indicate to the memory system controller 215, e.g., via the bus 235, that the data transfer to a memory device of the memory devices 240 has been completed.

In some cases, a storage queue 270 may be used to aid with the transfer of write data. For example, the memory system controller 215 may push (e.g., via the bus 235) write commands from the buffer queue 265 to the storage queue 270 for processing. The storage queue 270 may include entries for each access command. In some examples, the storage queue 270 may additionally include a buffer pointer (e.g., an address) that may indicate where in the buffer 225 the data associated with the command is stored and a storage pointer (e.g., an address) that may indicate the location in the memory devices 240 associated with the data. In some cases, the storage controller 230 may obtain from the buffer 225, buffer queue 265, or storage queue 270 the location within the buffer 225 from which to obtain the data. The storage controller 230 may manage the locations within the memory devices 240 to store the data (e.g., performing wear-leveling, garbage collection, and the like). The entries may be added to the storage queue 270, e.g., by the memory system controller 215. The entries may be removed from the storage queue 270, e.g., by the storage controller 230 or memory system controller 215 upon completion of the transfer of the data.

To process a read command received from the host system 205, the memory system controller 215 may again first determine if the buffer 225 has sufficient available space to store the data associated with the command. For example, the memory system controller 215 may determine, e.g., via firmware (e.g., controller firmware), an amount of space within the buffer 225 that may be available to store data associated with the read command.

In some cases, the buffer queue 265 may be used to aid with buffer storage of data associated with read commands in a similar manner as discussed with respect to write commands. For example, if the buffer 225 has sufficient space to store the read data, the memory system controller 215 may cause the storage controller 230 to retrieve the data associated with the read command from a memory device 240 and store the data in the buffer 225 for temporary storage using the data path 250. The storage controller 230 may indicate to the memory system controller 215, e.g., via the bus 235, when the data transfer to the buffer 225 has been completed.

In some cases, the storage queue 270 may be used to aid with the transfer of read data. For example, the memory system controller 215 may push the read command to the storage queue 270 for processing. In some cases, the storage controller 230 may obtain from the buffer 225 or storage queue 270 the location within the memory devices 240 from which to retrieve the data. In some cases, the storage controller 230 may obtain from the buffer queue 265 the location within the buffer 225 to store the data. In some cases, the storage controller 230 may obtain from the storage queue 270 the location within the buffer 225 to store the data. In some cases, the memory system controller 215 may move the command processed by the storage queue 270 back to the command queue 260.

Once the data has been stored in the buffer 225 by the storage controller 230, the data may be transferred out of the buffer 225 and sent to the host system 205. For example, the memory system controller 215 may cause the interface 220 to retrieve the data out of the buffer 225 using the data path 250 and transmit the data to the host system 205, e.g., according to a protocol (e.g., a UFS protocol or an eMMC protocol). For example, the interface 220 may process the command from the command queue 260 and may indicate to the memory system controller 215, e.g., via the bus 235, that the data transmission to the host system 205 has been completed.

The memory system controller 215 may execute received commands according to an order (e.g., a first-in, first-out order, according to the order of the command queue 260). For each command, the memory system controller 215 may cause data corresponding to the command to be moved into and out of the buffer 225, as discussed herein. As the data is moved into and stored within the buffer 225, the command may remain in the buffer queue 265. A command may be removed from the buffer queue 265, e.g., by the memory system controller 215, if the processing of the command has been completed (e.g., if data corresponding to the access command has been transferred out of the buffer 225). If a command is removed from the buffer queue 265, the address previously storing the data associated with that command may be available to store data associated with a new command.

The memory system controller 215 may additionally be configured for operations associated with the memory devices 240. For example, the memory system controller 215 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., LBAs) associated with commands from the host system 205 and physical addresses (e.g., physical block addresses) associated with memory cells within the memory devices 240. That is, the host system 205 may issue commands indicating one or more LBAs and the memory system controller 215 may identify one or more physical block addresses indicated by the LBAs. In some cases, one or more contiguous LBAs may correspond to noncontiguous physical block addresses. In some cases, the storage controller 230 may be configured to perform one or more of the described operations in conjunction with or instead of the memory system controller 215. In some cases, the memory system controller 215 may perform the functions of the storage controller 230 and the storage controller 230 may be omitted.

In some examples, a memory system 210 may operate in accordance with trim settings stored in non-volatile memory (e.g., in one or more blocks of the memory device 240). Because errors in the trim settings may cause the memory system 210 to fail, the memory system 210 may be configured to store one or more copies of the trim settings to serve as a backup (e.g., one or more backups) in case the primary trim settings include an error. In such examples, the memory system 210 may load data (e.g., a data packet) including one or more copies of the trim settings to the non-volatile memory (e.g., from a volatile memory cache, one or more blocks of volatile memory cells) as part of a start-up procedure, where the data is written to the volatile memory from a register (e.g., a non-volatile register) of the memory system 210.

In accordance with examples as disclosed herein, a memory system 210 may store one or more trim settings to a volatile memory in a compressed manner, and may expand (e.g., decompress) the data as part of a write operation to a non-volatile memory (e.g., during a start-up procedure). For example, compressed (e.g., non-expanded) trim data may be stored to a volatile memory, and a portion of the volatile memory (e.g., one or more blocks of volatile memory cells) may be temporarily allocated to expand the data (e.g., copy the data, invert the data, copy the inverted data). Once the data is expanded, it may be stored in the non-volatile memory, and the temporarily allocated portion of the volatile memory may be reallocated (e.g., allocated for another purpose). The expanded data may include multiple copies of the trim settings, and such redundancies may ensure proper operation of the memory system 210 (e.g., in accordance with the trim settings). Moreover, by storing compressed data in the volatile memory, storage capabilities and overall performance of the memory system 210 may be improved.

FIG. 3 illustrates an example of a system 300 that supports compression and decompression of trim data in accordance with examples as disclosed herein. The system 300 may include a host system 305 and a memory system 310, where the host system 305 may be an example of a host system 205 and the memory system 310 may be an example of a memory system 210 as described with reference to FIG. 2. In some examples, the memory system 310 may include volatile memory 315, first circuitry 320, second circuitry 325, and non-volatile memory 330. In some examples, the memory system 310 may be configured to operate in accordance with trim data stored in the non-volatile memory 330, where compressed trim data stored in the volatile memory 315 is expanded and transferred to the non-volatile memory 330 (e.g., in association with a start-up procedure, in response to a command to update trim data). By storing compressed data in the volatile memory 315, storage capabilities and overall performance of the memory system 310 may be improved.

The volatile memory 315 (e.g., an array of volatile memory cells, a set of volatile memory cells) may be configured as a cache (e.g., a volatile memory cache) and may include one or more volatile memory cells configured to store data. In some examples, the memory system 310 may be configured to allocate (e.g., temporary allocate) portions of the volatile memory 315 to support various operations of the memory system 310. For example, trim data associated with the memory system 310 may be stored (e.g., temporarily stored) to the volatile memory 315 before being written to the non-volatile memory 330.

The non-volatile memory 330 may include one or more memory blocks (e.g., one or more blocks of non-volatile memory cells) configured to store data. For example, the non-volatile memory 330 may store trim data, where the trim data is expanded and written to the non-volatile memory 330 from the volatile memory 315 (e.g., as part of a start-up procedure, to update one or more trim settings).

The first circuitry 320 and the second circuitry 325 may communicate trim data between the volatile memory 315 and the non-volatile memory 330. For example, the first circuitry 320 may be configured to expand (e.g., decompress) and contract (e.g., compress) trim data in accordance with one or more functions of the first circuitry 320, where the first circuitry 320 may be operable to generate or remove copies of one or more data elements (e.g., one or more bytes) of the trim data. The first circuitry 320 may be further operable to invert one or more data elements of the trim data. For example, upon expanding the trim data as described herein, the first circuitry 320 may invert one or more of the expanded data elements before the expanded trim data is written to the non-volatile memory 330.

The second circuitry 325 may be configured to perform access operations (e.g., read operations, write operations) on the non-volatile memory 330 and, as such, the second circuitry 325 may communicate data to and from the non-volatile memory 330 (e.g., between the volatile memory 315 and the non-volatile memory 330). In such examples, the first circuitry 320 and the second circuitry 325 may be included within a controller (e.g., a memory system controller 215 as described with reference to FIG. 2) or may function as standalone circuitry of the memory system 310. Additionally or alternatively, the first circuitry 320 and the second circuitry 325 may include a direct memory access (DMA) engine, where the first circuitry 320 may be an example of a magnetoresistive RAM (MRAM) DMA engine and the second circuitry 325 may be an example of a near-field communication (NFC) DMA engine.

In some examples, the memory system 310 may initiate a start-up procedure (e.g., at boot-up, after transitioning from a first power state to a second, higher power state). As part of the start-up procedure, the memory system 310 may store first data 355 in the volatile memory 315. For example, the memory system 310 may read the first data 355 from a register (e.g., a non-volatile register, not shown) and may write the first data 355 to the volatile memory 315 (e.g., a first subset of the set of memory cells). In such examples, the first data 355 may be stored in the register during a manufacturing process, and may be updated (e.g., updated at the register) in accordance with a command to update trim settings from the host system 305.

Additionally or alternatively, the memory system 310 may store the first data 355 in the volatile memory 315 in accordance with a command (e.g., a command to initiate the start-up procedure, a command including first data 355) received from the host system 305, where the command may boot (or initiate a boot sequence) the memory system 310. Upon the memory system 310 booting-up the first data 355 may be stored to the volatile memory 315. In some cases, the memory system 310 may allocate (e.g., temporarily allocate) a portion of the volatile memory 315 (e.g., a second subset of the set of memory cells) to store second data 360 for a duration (e.g., during which the first circuitry 320 generates the second data 360).

In some cases, the first data 355 may be an example of compressed trim data. For instance, the first data 355 may include a plurality of data elements (e.g., a first plurality of data elements) that includes at least a lower end address 335, an upper end address 340, masked data 345, and data 350. The lower end address 335 and the upper end address 340 may specify locations in the non-volatile memory 330 to which the trim data is stored (or to be stored to). For example, the lower end address 335 and the upper end address 340 may specify an address range in the non-volatile memory 330, defined by a lower boundary and an upper boundary, respectively, at which the trim data is stored. The masked data 345 and the data 350 may include the trim data (e.g., one or more trim settings), and may be stored to the non-volatile memory 330 in accordance with the lower end address 335 and the upper end address 340 (e.g., at a later step in the start-up procedure).

In some examples, the memory system 310 may operate (e.g., as part of a standard operating mode) in accordance with the masked data 345 and the data 350. The masked data 345 may represent the data 350 following encryption to obfuscate trim data in accordance with one or more security features or settings of the memory system 310. In such examples, the first data 355 may include a relatively small quantity of bytes (e.g., 4 bytes) due to the first data 355 not including any redundant data elements (e.g., one or more copies of the plurality of data elements). Accordingly, the first data 355 may occupy a relatively small portion of the volatile memory 315 compared with conventional storage techniques.

The first circuitry 320 may be operable to generate second data 360 using the first data 355, where the second data 360 may be an example of expanded (e.g., decompressed) trim data (e.g., expanded from the first data 355) that includes a second plurality of data elements. The second data 360 may be generated by the first circuitry 320 using the temporarily allocated portion of the volatile memory 315. In some examples, the first circuitry 320 may generate a portion 365 of the second data 360 by copying the first plurality of data elements (e.g., generating one or more copies of each data element). The portion 365 may include a portion of the second plurality of data elements (e.g., half of the second plurality of data elements, a subset of the plurality of data elements, 32 data elements) that are ultimately stored to the non-volatile memory 330. For example, the portion 365 may include one or more copies (e.g., multiple copies, 8 copies) of each of the lower end address 335, the upper end address 340, the masked data 345, and the data 350.

In some cases, data elements of the portion 365 may be organized in words 375 (e.g., data words), where each word 375 includes more than one data element (e.g., four copies of a same data element, four bytes of data). In such cases, the words 375 may follow a specific arrangement within the portion 365, where two words 375-a (e.g., each including more than one copy of the lower end address 335) and two words 375-b (e.g., each including more than one copy of the upper end address 340) may alternate in a first subset of the portion 365 and two words 375-c (e.g., each including more than one copy of the masked data 345) and two words 375-d (e.g., each including more than one copy of the data 350) may alternate in a second subset of the portion 365.

In some examples, the first circuitry 320 may generate a portion 370 of the second data 360 (e.g., after generating the portion 365), where the portion 370 may include a portion of the second plurality of data elements (e.g., a subset of the second plurality of data elements, half of the second plurality of data elements, 32 data elements) that are ultimately stored to the non-volatile memory 330. The first circuitry 320 may generate the portion 370 from the portion 365 by copying the portion 365 (e.g., each data element of the portion 365) and inverting each copied data element. As such, the portion 370 may include a same quantity of inverted copies of each of the lower end address 335, the upper end address 340, the masked data 345, and the data 350. The data elements may be arranged within the portion 370 in a substantially similar manner as data elements are arranged in the portion 365 (e.g., in a plurality of words 375 following a same or similar arrangement). The second data 360 may include both the portion 365 and the portion 370 (e.g., a sum of the data elements included in the portion 365 and the portion 370, 64 data elements, 64 bytes). The second data 360 may thus include multiple copies of each of the first plurality of data elements to aid in error detection and correction of the trim data (e.g., in accordance with an error correction code (ECC) scheme).

In some cases, the second circuitry 325 may store the second data 360 to the non-volatile memory 330. For example, the second circuitry 325 may read the second data 360 from volatile memory 315 (e.g., from the temporarily allocated portion of the volatile memory 315) and write the second data 360 to the non-volatile memory 330 (e.g., after the duration). The second circuitry 325 may write the second data 360 to locations in the non-volatile memory 330 specified by the lower end address 335 and the upper end address 340.

In such cases, after writing the second data 360 to the non-volatile memory 330, the temporarily allocated portion of the volatile memory 315 may no longer include the second data 360, and the memory system 310 may deallocate the temporarily allocated portion of the volatile memory 315 (e.g., allocate for various other purposes) following the storage operations. For example, the portion of the volatile memory 315 may serve as a buffer to facilitate access operations (e.g., read operations, write operations) to the non-volatile memory 330. The first data 355 may continue to be stored in the volatile memory 315 (e.g., in the dedicated portion of the volatile memory 315). Alternatively, the memory system 310 may remove (e.g., erase) the first data 355 from the volatile memory 315, and may write (e.g., rewrite) the first data 355 from the register as part of subsequent boot-up procedures.

The memory system 310 may operate (e.g., as part of a general operating mode, following the start-up procedure) in accordance with the second data 360 stored in the non-volatile memory 330. For example, the memory system 310 may operate in accordance with one or more trim settings included in the second data 360, where the trim settings may define various aspects of operation (e.g., signaling magnitude, voltage thresholds, memory cell configuration, for example) for memory system 310. By generating the second data 360 using the first data 355, the volatile memory 315 may have improved storage capabilities. Moreover, because the first data 355 may be relatively smaller than the second data 360 (e.g., the first data 355 may include fewer bytes than the second data 360), the volatile memory 315 may have additional storage space to support various other operations of the memory system 310 while the first data is stored to the volatile memory 315. Further, temporary allocating a portion of the volatile memory 315 for expanding the trim data may allow for a flexible system architecture and thereby improve the general efficiency of the memory system 310.

In some cases, the memory system 310 may receive a command to update trim data (e.g., the second data 360) from the host system 305. The command may include third data (not shown) that includes a third plurality of data elements, where the third plurality of data elements may include one or more updated trim settings (e.g., compared to the first data 355, compared to the second data 360). For example, the third plurality of data elements may include an updated version of at least the masked data 345 and the data 350. The third data may be an example of compressed trim data, and may include a same or similar quantity of bytes as the first data 355.

In some examples, to update the trim data, the memory system 310 may overwrite the first data 355 stored to the volatile memory 315 with the third data. The memory system 310 may temporarily allocate a portion of the volatile memory 315 for a second duration (e.g., for a second time, a subsequent time) to store fourth data (e.g., updated second data, expanded trim data). In some cases, the first circuitry 320 may expand (e.g., decompress) the third data to generate fourth data (not shown) during the second duration. The first circuitry 320 may generate the fourth data using the temporarily allocated portion of the volatile memory 315 by copying and inverting one or more data elements of the third plurality of data elements in a same or similar manner as described above to generate the second data 360.

In such cases, the fourth data may include a fourth plurality of data elements, where the fourth plurality of data elements includes the same or similar quantity of data elements as the second plurality of data elements (e.g., a sum of the data elements included in each portion of the fourth data, 64 data elements). The fourth data may include one or more copies and inverted copies of updated data elements from the third plurality of data elements. Additionally or alternatively, the second circuitry 325 may then overwrite the second data 360 stored in the non-volatile memory 330 with the fourth data. The memory system 310 may deallocate the temporarily allocated portion of the volatile memory 315, and may operate in accordance with the updated trim data stored to the non-volatile memory 330.

In some examples, the memory system 310 may temporarily allocate a portion of the volatile memory 315 to store second data 360 for a third duration. In some cases, the second circuitry 325 may read the second data 360 from the non-volatile memory 330 and may write the second data 360 to the temporarily allocated portion of the volatile memory 315. During the third duration, the first circuitry 320 may compress the second data 360 to generate the first data 355 using the temporarily allocated portion of the volatile memory 315. To compress the second data 360, the first circuitry 320 may remove copies and inverted copies of the first plurality of data elements from the second plurality of data elements. For example, the first circuitry 320 may remove the portion 370 from the second data 360 and one or more copies of each of the lower end address 335, the upper end address 340, the masked data 345, and the data 350 from the portion 365 of the second data 360 to generate a copy of the first data 355.

In such cases, the memory system 310 may then replace (e.g., overwrite) one or more data elements (e.g., the masked data 345, the data 350) of the copy of the first data 355 with updated trim settings included in the command to generate the third data. The memory system 310 may then overwrite the first data 355 (e.g., the original first data 355) with the third data, and generate and store the fourth data to the non-volatile memory 330 as described herein. By storing compressed data in the volatile memory 315, storage capabilities and overall performance of the memory system 310 may be improved.

FIG. 4 illustrates an example of a process flow diagram 400 that supports compression and decompression of trim data in accordance with examples as disclosed herein. In some examples, the process flow diagram 400 may illustrate techniques for compression and expansion of trim data for a memory system 410. The memory system 410 may be coupled with a host system 405 and may include volatile memory 415, first circuitry 420, second circuitry 425, and non-volatile memory 430. In some cases, the host system 405 may be an example of the host system 305 and the memory system 410 may be an example of the memory system 310 described with reference to the FIG. 3. As part of a start-up procedure, the memory system 410 may store compressed trim data (e.g., including one or more trim settings) in the volatile memory 415. Then, the memory system 410 may expand and store the trim data to the non-volatile memory 430. By storing compressed data in the volatile memory 415, storage capabilities and overall performance of the memory system 410 may be improved.

Alternative examples of the process flow diagram 400 may be implemented, where some steps are performed in a different order than described or not performed. In some cases, steps may include additional features not mentioned below, or further steps may be added. Aspects of the process flow diagram 400 may be implemented by a controller, among other components. Additionally or alternatively, aspects of the process flow diagram 400 may be implemented as instructions stored in memory (e.g., firmware stored in a memory coupled with the memory system 410). For example, the instructions, when executed by a controller (e.g., a memory system controller 115), may cause the controller to perform the operations of the process flow diagram 400.

At 435, the power state may transition. For example, the memory system 410 may transition from a first power state to a second power state that higher than the first power state. In some cases, the first power state may be an example of an ‘OFF’ state of the memory system 410 and the second power state may be an example of an ‘ON’ state of the memory system 410. In such examples, (e.g., in response to a power transition) the memory system 410 may initiate a start-up procedure to load trim data (e.g., de-compressed trim data) to the non-volatile memory 430.

At 440, first data may be stored to the volatile memory 415. In some cases, the memory system 410 may store the first data to the volatile memory 415 by reading the first data from a register (e.g., a non-volatile register, not shown) and writing the first data to the volatile memory 415 (e.g., a first subset of the volatile memory 415). In such cases, the first data may be an example of compressed trim data including a first plurality of data elements (e.g., bytes).

At 445, a portion of the volatile memory 415 (e.g., a second subset set of the volatile memory 415) may be temporarily allocated for expanding the trim data. For example, the memory system 410 may temporarily allocate (e.g., reserve) a portion of the volatile memory 415 to store second data (e.g., expanded data, de-compressed data) over a duration. In such examples, second data may be generated in the temporarily allocated portion of the volatile memory 415 during the duration.

At 450, the second data may be generated. For example, the first circuitry 420 may generate the second data by generating one or more copies of the first plurality of data elements and subsequently inverting a portion of the one or more copies in the temporarily allocated portion of the volatile memory 415. The first circuitry 420 may copy each of the first plurality of data elements one or more times (e.g., multiple times, 8 times) and may invert the one or more copies of each of the first plurality of data elements to generate the second data. The second data may include a second plurality of data elements greater than the first plurality of data elements. In such examples, the second plurality of data elements may include one or more data elements redundant to (e.g., a copy of) each of the first plurality of data elements.

At 455, the second data may be stored. For example, the second circuitry 425 may store the second data to the non-volatile memory 430 by reading the second data from the temporarily allocated portion of the volatile memory 415 (e.g., after the duration) and writing the second data to the non-volatile memory 430. In some cases, the first data, the second data, or both may be removed (e.g., erased) from the volatile memory 415. Alternatively, the first data may remain stored in the volatile memory 415. In such examples, the memory system 410 may operate (e.g., as part of a general operation) in accordance with the second data stored in the non-volatile memory 430 (e.g., following the start-up procedure). By storing compressed trim data in the volatile memory 415 and subsequently expanding it, the memory system 410 may utilize storage space of the volatile memory 415 more efficiently, thereby improving overall performance of the memory system 410.

In some examples, at 460, the portion of the volatile memory 415 may be deallocated. For example, the memory system 410 may deallocate (e.g., allocate for various other operations) the portion of the volatile memory 415 following the duration (e.g., after storing second data at 455). Additionally or alternatively, the memory system 410 may deallocate the portion of the volatile memory 415 in response to reading the second data from the volatile memory 415. After deallocating the portion of the volatile memory 415, the memory system 410 may utilize the portion of the volatile memory 415 for other operations including as a buffer to facilitate access operations performed on the non-volatile memory 430.

At 465, an update command may be received. For example, the memory system 410 may receive a command to update the trim data (e.g., update one or more trim settings) from the host system 405. In some cases, the update command may include third data, where the third data may be an example of compressed trim data including a third plurality of elements. The third plurality of elements may include the same or similar quantity of elements as the first plurality of elements, and one or more of the third plurality of elements may be different than corresponding data elements of the first plurality of data elements.

At 470, the first data may be overwritten. For example, the memory system 410 may overwrite the first data stored in the volatile memory 415 with the third data (e.g., updated compressed trim data). In some cases, the memory system 410 may temporarily allocate a portion of the volatile memory 415 to store expanded trim data (e.g., to generate fourth data) over a second duration. Additionally or alternatively, the temporarily allocated portion of the volatile memory 415 may be used to compress trim data.

In other examples, the second circuitry 425 may read the second data from the non-volatile memory 430 and write the second data to the temporarily allocated portion of the volatile memory 415. The first circuitry 420 may generate first data using the second data in the temporarily allocated portion of the volatile memory 415. For example, the first circuitry 420 may compress the second data by removing copies and inverted copies of the first plurality of data elements included in the second plurality of data elements to generate the first data. In such cases, the memory system 410 may then replace (e.g., overwrite) one or more data elements of the first data with updated trim settings included in the command received from the host system (e.g., at 465) to generate the third data. In some cases, the memory system 410 may then overwrite the first data with the third data. In some other cases, if the first data is not stored in the volatile memory 415, the memory system may write the third data to a different location of the volatile memory 415 (e.g., not included in the temporarily allocated portion of the volatile memory 415).

At 475, fourth data may be generated. For example, the first circuitry 420 may generate fourth data (e.g., expanded trim data, updated second data) from the third data using the temporarily allocated portion of the volatile memory 415. The first circuitry 420 may generate the fourth data by copying and inverting one or more data elements of the third plurality of data elements as described above in reference to generating the second data from the first data. In such examples, the fourth data may include a fourth plurality of data elements that includes a same quantity of data elements as the second plurality of data elements. Additionally or alternatively, the fourth plurality of data elements may include the third plurality of data elements (e.g., one or more copies of the third plurality of data elements) and may represent updated trim data with respect to the second data.

At 480, the second data may be overwritten. For example, the second circuitry 425 may overwrite the second data in the non-volatile memory 430 with the fourth data. The second circuitry 425 may overwrite the second data by reading the fourth data from the temporarily allocated portion of the volatile memory 415 and writing (e.g., overwriting) the fourth data to the non-volatile memory 430 (e.g., at locations occupied by the second data). In such examples, the portion of the volatile memory may be deallocated (e.g., following the second data, after overwriting the second data), and the memory system 410 may operate in accordance with the updated trim data included in the fourth data. By storing compressed data in the volatile memory 415, storage capabilities and overall performance of the memory system 410 may be improved.

FIG. 5 shows a block diagram 500 of a memory system 520 that supports compression and decompression of trim data in accordance with examples as disclosed herein. The memory system 520 may be an example of aspects of a memory system as described with reference to FIGS. 1 through 4. The memory system 520, or various components thereof, may be an example of means for performing various aspects of compression and decompression of trim data as described herein. For example, the memory system 520 may include a volatile storage component 525, a data generating component 530, a non-volatile storage component 535, a storage allocation component 540, a command reception component 545, a power transition component 550, or any combination thereof. Each of these components may communicate, directly or indirectly, with one another (e.g., via one or more buses).

The volatile storage component 525 may be configured as or otherwise support a means for storing, to an array of volatile memory cells of a memory system, first data including a first plurality of data elements associated with one or more trim settings for the memory system. The data generating component 530 may be configured as or otherwise support a means for generating second data based at least in part on storing the first data including the first plurality of data elements associated with one or more trim settings, the second data including a second plurality of data elements associated with the one or more trim settings for the memory system and greater in quantity than the first plurality of data elements. The non-volatile storage component 535 may be configured as or otherwise support a means for storing, to an array of non-volatile memory cells of the memory system, the second data including the second plurality of data elements based at least in part on generating the second data.

In some examples, to support generating the second data, the data generating component 530 may be configured as or otherwise support a means for generating at least one copy of each data element of the first plurality of data elements, where the second plurality of data elements includes the at least one copy of each data element of the first plurality of data elements.

In some examples, the data generating component 530 may be configured as or otherwise support a means for inverting each data element of the first plurality of data elements, where the second plurality of data elements includes a plurality of data elements that are inverted relative to a corresponding data element of the first plurality of data elements.

In some examples, the data generating component 530 may be configured as or otherwise support a means for generating at least one copy of each inverted first plurality of data elements included in the second plurality of data elements, where the second plurality of data elements includes the at least one copy of each inverted first plurality of data elements.

In some examples, the storage allocation component 540 may be configured as or otherwise support a means for allocating a set of memory cells of the array of volatile memory cells for storing the one or more trim settings for the memory system, where the first plurality of data elements are stored to a first subset of the set of memory cells of the array of volatile memory cells.

In some examples, to support generating the second data, the volatile storage component 525 may be configured as or otherwise support a means for storing, for a duration, the second plurality of data elements in a second subset of the set of memory cells of the array of volatile memory cells, where the second data including the second plurality of data elements is stored to the array of non-volatile memory cells after the duration.

In some examples, the storage allocation component 540 may be configured as or otherwise support a means for deallocating the second subset of the set of memory cells of the array of volatile memory cells for storing the one or more trim settings for the memory system based at least in part on storing the second data including the second plurality of data elements to the array of non-volatile memory cells.

In some examples, the command reception component 545 may be configured as or otherwise support a means for receiving, from a host system, a command to update the second data, the command including third data including a third plurality of data elements associated with one or more updated trim settings for the memory system. In some examples, the data generating component 530 may be configured as or otherwise support a means for generating fourth data based at least in part on receiving the command to update the second data, where the fourth data includes a fourth plurality of data elements, the fourth plurality of data elements including a same quantity of data elements as the second plurality of data elements. In some examples, the non-volatile storage component 535 may be configured as or otherwise support a means for overwriting the second data including the second plurality of data elements stored to the array of non-volatile memory cells with the fourth data including the third plurality of data elements.

In some examples, the third plurality of data elements includes a same quantity of data elements as the first plurality of data elements, and the data generating component 530 may be configured as or otherwise support a means for overwriting the first data including the first plurality of data elements stored to the array of volatile memory cells with the third data including the third plurality of data elements.

In some examples, the power transition component 550 may be configured as or otherwise support a means for transitioning, by the memory system, from a first power state to a second power state that is higher than the first power state, where storing the first data including the first plurality of data elements to the array of volatile memory cells is based at least in part on transitioning from the first power state to the second power state.

In some examples, the power transition component 550 may be configured as or otherwise support a means for reading the first data including the first plurality of data elements from a register of the memory system based at least in part on transitioning from the first power state to the second power state, where storing the first data including the first plurality of data elements to the array of volatile memory cells is based at least in part on reading the first data including the first plurality of data elements from the register.

In some examples, a subset of the second plurality of data elements is redundant to the first plurality of data elements.

FIG. 6 shows a flowchart illustrating a method 600 that supports compression and decompression of trim data in accordance with examples as disclosed herein. The operations of method 600 may be implemented by a memory system or its components as described herein. For example, the operations of method 600 may be performed by a memory system as described with reference to FIGS. 1 through 5. In some examples, a memory system may execute a set of instructions to control the functional elements of the device to perform the described functions. Additionally, or alternatively, the memory system may perform aspects of the described functions using special-purpose hardware.

At 605, the method may include storing, to an array of volatile memory cells of a memory system, first data including a first plurality of data elements associated with one or more trim settings for the memory system. The operations of 605 may be performed in accordance with examples as disclosed herein. In some examples, aspects of the operations of 605 may be performed by a volatile storage component 525 as described with reference to FIG. 5.

At 610, the method may include generating second data based at least in part on storing the first data including the first plurality of data elements associated with one or more trim settings, the second data including a second plurality of data elements associated with the one or more trim settings for the memory system and greater in quantity than the first plurality of data elements. The operations of 610 may be performed in accordance with examples as disclosed herein. In some examples, aspects of the operations of 610 may be performed by a data generating component 530 as described with reference to FIG. 5.

At 615, the method may include storing, to an array of non-volatile memory cells of the memory system, the second data including the second plurality of data elements based at least in part on generating the second data. The operations of 615 may be performed in accordance with examples as disclosed herein. In some examples, aspects of the operations of 615 may be performed by a non-volatile storage component 535 as described with reference to FIG. 5.

In some examples, an apparatus as described herein may perform a method or methods, such as the method 600. The apparatus may include features, circuitry, logic, means, or instructions (e.g., a non-transitory computer-readable medium storing instructions executable by a processor), or any combination thereof for performing the following aspects of the present disclosure:
Aspect 1: A method, apparatus, or non-transitory computer-readable medium including operations, features, circuitry, logic, means, or instructions, or any combination thereof for storing, to an array of volatile memory cells of a memory system, first data including a first plurality of data elements associated with one or more trim settings for the memory system; generating second data based at least in part on storing the first data including the first plurality of data elements associated with one or more trim settings, the second data including a second plurality of data elements associated with the one or more trim settings for the memory system and greater in quantity than the first plurality of data elements; and storing, to an array of non-volatile memory cells of the memory system, the second data including the second plurality of data elements based at least in part on generating the second data.
Aspect 2: The method, apparatus, or non-transitory computer-readable medium of aspect 1 where generating the second data includes operations, features, circuitry, logic, means, or instructions, or any combination thereof for generating at least one copy of each data element of the first plurality of data elements, where the second plurality of data elements includes the at least one copy of each data element of the first plurality of data elements.
Aspect 3: The method, apparatus, or non-transitory computer-readable medium of aspect 2, further including operations, features, circuitry, logic, means, or instructions, or any combination thereof for inverting each data element of the first plurality of data elements, where the second plurality of data elements includes a plurality of data elements that are inverted relative to a corresponding data element of the first plurality of data elements.
Aspect 4: The method, apparatus, or non-transitory computer-readable medium of aspect 3, further including operations, features, circuitry, logic, means, or instructions, or any combination thereof for generating at least one copy of each inverted first plurality of data elements included in the second plurality of data elements, where the second plurality of data elements includes the at least one copy of each inverted first plurality of data elements.
Aspect 5: The method, apparatus, or non-transitory computer-readable medium of any of aspects 1 through 4, further including operations, features, circuitry, logic, means, or instructions, or any combination thereof for allocating a set of memory cells of the array of volatile memory cells for storing the one or more trim settings for the memory system, where the first plurality of data elements are stored to a first subset of the set of memory cells of the array of volatile memory cells.
Aspect 6: The method, apparatus, or non-transitory computer-readable medium of aspect 5 where generating the second data includes operations, features, circuitry, logic, means, or instructions, or any combination thereof for storing, for a duration, the second plurality of data elements in a second subset of the set of memory cells of the array of volatile memory cells, where the second data including the second plurality of data elements is stored to the array of non-volatile memory cells after the duration.
Aspect 7: The method, apparatus, or non-transitory computer-readable medium of aspect 6, further including operations, features, circuitry, logic, means, or instructions, or any combination thereof for deallocating the second subset of the set of memory cells of the array of volatile memory cells for storing the one or more trim settings for the memory system based at least in part on storing the second data including the second plurality of data elements to the array of non-volatile memory cells.
Aspect 8: The method, apparatus, or non-transitory computer-readable medium of any of aspects 1 through 7, further including operations, features, circuitry, logic, means, or instructions, or any combination thereof for receiving, from a host system, a command to update the second data, the command including third data including a third plurality of data elements associated with one or more updated trim settings for the memory system; generating fourth data based at least in part on receiving the command to update the second data, where the fourth data includes a fourth plurality of data elements, the fourth plurality of data elements including a same quantity of data elements as the second plurality of data elements; and overwriting the second data including the second plurality of data elements stored to the array of non-volatile memory cells with the fourth data including the third plurality of data elements.
Aspect 9: The method, apparatus, or non-transitory computer-readable medium of aspect 8 where the third plurality of data elements includes a same quantity of data elements as the first plurality of data elements and the method, apparatuses, and non-transitory computer-readable medium, further includes operations, features, circuitry, logic, means, or instructions, or any combination thereof for overwriting the first data including the first plurality of data elements stored to the array of volatile memory cells with the third data including the third plurality of data elements.
Aspect 10: The method, apparatus, or non-transitory computer-readable medium of any of aspects 1 through 9, further including operations, features, circuitry, logic, means, or instructions, or any combination thereof for transitioning, by the memory system, from a first power state to a second power state that is higher than the first power state, where storing the first data including the first plurality of data elements to the array of volatile memory cells is based at least in part on transitioning from the first power state to the second power state.
Aspect 11: The method, apparatus, or non-transitory computer-readable medium of aspect 10, further including operations, features, circuitry, logic, means, or instructions, or any combination thereof for reading the first data including the first plurality of data elements from a register of the memory system based at least in part on transitioning from the first power state to the second power state, where storing the first data including the first plurality of data elements to the array of volatile memory cells is based at least in part on reading the first data including the first plurality of data elements from the register.
Aspect 12: The method, apparatus, or non-transitory computer-readable medium of any of aspects 1 through 11 where a subset of the second plurality of data elements is redundant to the first plurality of data elements.

It should be noted that the described techniques include possible implementations, and that the operations and the steps may be rearranged or otherwise modified and that other implementations are possible. Further, portions from two or more of the methods may be combined.

An apparatus is described. The following provides an overview of aspects of the apparatus as described herein:
Aspect 13: An apparatus, including: an array of volatile memory cells configured to store first data; an array of non-volatile memory cells; first circuitry coupled with the array of volatile memory cells and configured to generate second data based at least in part on the array of volatile memory cells being configured to store the first data, the first data including a first plurality of data elements associated with one or more trim settings and the second data including a second plurality of data elements greater than the first plurality of data elements; and second circuitry coupled with the first circuitry and the array of non-volatile memory cells, the second circuitry configured to obtain the second data from the first circuitry and write the second data to the array of non-volatile memory cells.
Aspect 14: The apparatus of aspect 13, where the first circuitry is configured to: generate at least one copy of each data element of the first plurality of data elements, where the second plurality of data elements includes the at least one copy of each data element of the first plurality of data elements.
Aspect 15: The apparatus of aspect 14, where the first circuitry is configured to: invert each data element of the first plurality of data elements, where the second plurality of data elements includes a plurality of data elements that are inverted relative to a corresponding data element of the first plurality of data elements.
Aspect 16: The apparatus of aspect 15, where the first circuitry is configured to: generate at least one copy of each inverted first plurality of data elements included in the second plurality of data elements, where the second plurality of data elements includes the at least one copy of each inverted first plurality of data elements.
Aspect 17: The apparatus of any of aspects 13 through 16, where a first portion of the array of volatile memory cells is allocated to store the first data including the first plurality of data elements, and a second portion of the array of volatile memory cells is temporarily allocated to store the second data including the second plurality of data elements.
Aspect 18: The apparatus of any of aspects 13 through 17, where a subset of the second plurality of data elements is redundant to the first plurality of data elements.

Information and signals described herein may be represented using any of a variety of different technologies and techniques. For example, data, instructions, commands, information, signals, bits, symbols, and chips that may be referenced throughout the description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” refers to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to providing an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor, the functions may be stored on or transmitted over, as one or more instructions or code, a computer-readable medium. Other examples and implementations are within the scope of the disclosure and appended claims. For example, due to the nature of software, the described functions can be implemented using software executed by a processor, hardware, firmware, hardwiring, or combinations of any of these. Features implementing functions may also be physically located at various positions, including being distributed such that portions of functions are implemented at different physical locations.

For example, the various illustrative blocks and components described in connection with the disclosure herein may be implemented or performed with a general-purpose processor, a DSP, an ASIC, an FPGA or other programmable logic device, discrete gate or transistor logic, discrete hardware components, or any combination thereof designed to perform the functions described herein. A general-purpose processor may be a microprocessor, but in the alternative, the processor may be any processor, controller, microcontroller, or state machine. A processor may be implemented as a combination of computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

Computer-readable media includes both non-transitory computer storage media and communication media including any medium that facilitates transfer of a computer program from one place to another. A non-transitory storage medium may be any available medium that can be accessed by a general purpose or special purpose computer. By way of example, and not limitation, non-transitory computer-readable media can comprise RAM, ROM, electrically erasable programmable read-only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include CD, laser disc, optical disc, digital versatile disc (DVD), floppy disk, and Blu-ray disc, where disks usually reproduce data magnetically, while discs reproduce data optically with lasers. Combinations of these are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus, comprising:
a memory system; and
a controller coupled with the memory system, wherein the controller is configured to cause the apparatus to:
store, to an array of volatile memory cells of the memory system, first data comprising a first plurality of data elements associated with one or more trim settings for the memory system;
generate second data based at least in part on storing the first data comprising the first plurality of data elements associated with one or more trim settings, the second data comprising a second plurality of data elements associated with the one or more trim settings for the memory system and greater in quantity than the first plurality of data elements; and
store, to an array of non-volatile memory cells of the memory system, the second data comprising the second plurality of data elements based at least in part on generating the second data.

2. The apparatus of claim 1, wherein generating the second data is configured to cause the apparatus to:
generate at least one copy of each data element of the first plurality of data elements, wherein the second plurality of data elements comprises the at least one copy of each data element of the first plurality of data elements.

3. The apparatus of claim 2, wherein the controller is further configured to cause the apparatus to:
invert each data element of the first plurality of data elements, wherein the second plurality of data elements comprises a plurality of data elements that are inverted relative to a corresponding data element of the first plurality of data elements.

4. The apparatus of claim 3, wherein the controller is further configured to cause the apparatus to:
generate at least one copy of each inverted first plurality of data elements included in the second plurality of data elements, wherein the second plurality of data elements comprises the at least one copy of each inverted first plurality of data elements.

5. The apparatus of claim 1, further comprising:
allocate a set of memory cells of the array of volatile memory cells for storing the one or more trim settings for the memory system, wherein the first plurality of data elements are stored to a first subset of the set of memory cells of the array of volatile memory cells.

6. The apparatus of claim 5, wherein generating the second data is configured to cause the apparatus to:
store, for a duration, the second plurality of data elements in a second subset of the set of memory cells of the array of volatile memory cells, wherein the second data comprising the second plurality of data elements is stored to the array of non-volatile memory cells after the duration.

7. The apparatus of claim 6, wherein the controller is further configured to cause the apparatus to:
deallocate the second subset of the set of memory cells of the array of volatile memory cells for storing the one or more trim settings for the memory system based at least in part on storing the second data comprising the second plurality of data elements to the array of non-volatile memory cells.

8. The apparatus of claim 1, wherein the controller is further configured to cause the apparatus to:
receive, from a host system, a command to update the second data, the command comprising third data comprising a third plurality of data elements associated with one or more updated trim settings for the memory system;
generate fourth data based at least in part on receiving the command to update the second data, wherein the fourth data comprises a fourth plurality of data elements, the fourth plurality of data elements comprising a same quantity of data elements as the second plurality of data elements; and
overwrite the second data comprising the second plurality of data elements stored to the array of non-volatile memory cells with the fourth data comprising the third plurality of data elements.

9. The apparatus of claim 8, wherein the third plurality of data elements comprises a same quantity of data elements as the first plurality of data elements, wherein the controller is further configured to cause the apparatus to:
overwrite the first data comprising the first plurality of data elements stored to the array of volatile memory cells with the third data comprising the third plurality of data elements.

10. The apparatus of claim 1, wherein the controller is further configured to cause the apparatus to:
transition from a first power state to a second power state that is higher than the first power state, wherein storing the first data comprising the first plurality of data elements to the array of volatile memory cells is based at least in part on transitioning from the first power state to the second power state.

11. The apparatus of claim 10, wherein the controller is further configured to cause the apparatus to:
read the first data comprising the first plurality of data elements from a register of the memory system based at least in part on transitioning from the first power state to the second power state, wherein storing the first data comprising the first plurality of data elements to the array of volatile memory cells is based at least in part on reading the first data comprising the first plurality of data elements from the register.

12. The apparatus of claim 1, wherein a subset of the second plurality of data elements is redundant to the first plurality of data elements.

13. An apparatus, comprising:
an array of volatile memory cells configured to store first data;
an array of non-volatile memory cells;
first circuitry coupled with the array of volatile memory cells and configured to generate second data based at least in part on the array of volatile memory cells being configured to store the first data, the first data comprising a first plurality of data elements associated with one or more trim settings and the second data comprising a second plurality of data elements greater than the first plurality of data elements; and
second circuitry coupled with the first circuitry and the array of non-volatile memory cells, the second circuitry configured to obtain the second data from the first circuitry and write the second data to the array of non-volatile memory cells.

14. The apparatus of claim 13, wherein the first circuitry is configured to:
generate at least one copy of each data element of the first plurality of data elements, wherein the second plurality of data elements comprises the at least one copy of each data element of the first plurality of data elements.

15. The apparatus of claim 14, wherein the first circuitry is configured to:
invert each data element of the first plurality of data elements, wherein the second plurality of data elements comprises a plurality of data elements that are inverted relative to a corresponding data element of the first plurality of data elements.

16. The apparatus of claim 15, wherein the first circuitry is configured to:
generate at least one copy of each inverted first plurality of data elements included in the second plurality of data elements, wherein the second plurality of data elements comprises the at least one copy of each inverted first plurality of data elements.

17. The apparatus of claim 13, wherein:
a first portion of the array of volatile memory cells is allocated to store the first data comprising the first plurality of data elements, and
a second portion of the array of volatile memory cells is temporarily allocated to store the second data comprising the second plurality of data elements.

18. The apparatus of claim 13, wherein a subset of the second plurality of data elements is redundant to the first plurality of data elements.

19. A method, comprising:
storing, to an array of volatile memory cells of a memory system, first data comprising a first plurality of data elements associated with one or more trim settings for the memory system;
generating second data based at least in part on storing the first data comprising the first plurality of data elements associated with one or more trim settings, the second data comprising a second plurality of data elements associated with the one or more trim settings for the memory system and greater in quantity than the first plurality of data elements; and
storing, to an array of non-volatile memory cells of the memory system, the second data comprising the second plurality of data elements based at least in part on generating the second data.

20. The method of claim 19, wherein generating the second data comprises:
generating at least one copy of each data element of the first plurality of data elements, wherein the second plurality of data elements comprises the at least one copy of each data element of the first plurality of data elements.

21. The method of claim 20, further comprising:
inverting each data element of the first plurality of data elements, wherein the second plurality of data elements comprises a plurality of data elements that are inverted relative to a corresponding data element of the first plurality of data elements.

22. The method of claim 21, further comprising:
generating at least one copy of each inverted first plurality of data elements included in the second plurality of data elements, wherein the second plurality of data elements comprises the at least one copy of each inverted first plurality of data elements.

23. The method of claim 19, further comprising:
allocating a set of memory cells of the array of volatile memory cells for storing the one or more trim settings for the memory system, wherein the first plurality of data elements are stored to a first subset of the set of memory cells of the array of volatile memory cells.

24. The method of claim 23, wherein generating the second data comprises:
storing, for a duration, the second plurality of data elements in a second subset of the set of memory cells of the array of volatile memory cells, wherein the second data comprising the second plurality of data elements is stored to the array of non-volatile memory cells after the duration.

25. The method of claim 24, further comprising:
deallocating the second subset of the set of memory cells of the array of volatile memory cells for storing the one or more trim settings for the memory system based at least in part on storing the second data comprising the second plurality of data elements to the array of non-volatile memory cells.
